(19) United States
(12) Patent Application Publication
(10) Pub. No.: US 2024/0304508 A1
(43) Pub. Date: Sep. 12, 2024

(54) MULTI-THICKNESS CHIP INTEGRATION INTO CAVITIES OF A HOST WAFER USING LATERAL DIELECTRIC MATERIAL

(71) Applicant: PseudolithIC, Inc., Santa Barbara, CA (US)

(72) Inventors: Florian Herrault, Agoura Hills, CA (US); Mark Solder, Santa Barbara, CA (US); Daniel S. Green, McLean, VA (US); James F. Buckwalter, Santa Barbara, CA (US)

(21) Appl. No.: 18/666,533

(22) Filed: May 16, 2024

Related U.S. Application Data
(63) Continuation-in-part of application No. 18/333,449, filed on Jun. 12, 2023.
Application No. 18/333,449 is a continuation of application No. 18/155,607, filed on Jan. 17, 2023, now Pat. No. 11,756,848.

(51) Int. Cl. H01L 23/31; H01L 21/56; H01L 23/00

(52) U.S. Cl. CPC H01L 23/3114; H01L 21/561; H01L 24/96; H01L 2224/96

(57) ABSTRACT

An electronic assembly has a backside capping layer, and a host wafer having a back surface bonded to a top surface of the backside capping layer except for cavities in the wafer formed over areas of the backside capping layer, the cavities having side surfaces of the wafer. First chiplets have a first thickness and backsides bonded directly to first portions of the areas of the top surface of the backside capping layer. Second chiplets have a second, thinner thickness and backsides bonded to second portions of the areas of the top surface of the backside capping layer. The backside of the second chiplets are directly bonded to metal backfill plugs of at second portions of the backside capping layer. A lateral bonding material bonds side surfaces of the first chiplets, the second chiplets and the plugs to side surfaces of the wafer.

### RELATED APPLICATION INFORMATION

The present application is a continuation-in-part of co-pending U.S. patent application Ser. No. 18/333,449 filed Jun. 12, 2023 entitled CHIP INTEGRATION INTO CAVITIES OF A HOST WAFER USING LATERAL DIELECTRIC MATERIAL BONDING, which is a continuation of U.S. patent application Ser. No. 18/155,607, filed Jan. 17, 2023 entitled CHIP INTEGRATION INTO CAVITIES OF A HOST WAFER USING LATERAL DIELECTRIC MATERIAL BONDING, now U.S. Pat. No. 11,756,848, all of which are incorporated herein by reference.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to a host wafer having circuitry and multi-thickness chips (or chiplets) within and laterally bonded to the sidewalls of cavities of the wafer, such as using lateral dielectric material and where the wafer and chips are fabricated separately.

### Description of the Related Art

Electronic assemblies, or hybrid circuits, comprise microelectronic circuits fabricated separately and assembled together so as to form a single component, which can itself be encapsulated in an electronic circuit package. Assembling microelectronic circuits fabricated separately allows, for example, testing of all the microelectronic circuits separately, prior to assembling them, which, in turn enables improved fabrication yields of the final component. This capability is particularly significant if some of the microelectronic circuits fabricated separately are difficult and/or expensive to manufacture. Assembling microelectronic circuits fabricated separately also allows combining of microelectronic circuits, which themselves employ different materials and different manufacturing processes, into a single final component. This capability can lead to higher circuit performance.

There exists a need for an electronic assembly using a host wafer having pre-fabricated interconnects and integrated circuitry, such as passive components, that connect to a wafer level microelectronics active chiplets (i.e., with transistors) integrated in through-wafer cavities of the host wafer. This need may for example be for an assembly for microwave or other radio frequency (RF) integrated circuits that decouple the fabrication of the active circuits (e.g., fabrication of the transistors) from the fabrication of the passive circuits (e.g., fabrication of the interconnects, resistors and capacitors). Satisfying this need will allow for much faster manufacturing of the circuits, at lower cost, and a scaling up of active device technologies to circuits without cost and cycle time burden.

### DESCRIPTION OF THE DRAWINGS

FIG. 1 is a schematic top view of a host wafer having cavities for in-substrate multi-thickness chiplet integration into the wafer cavities of the host wafer using lateral dielectric material.

FIG. 2 is a schematic top view of a first set of multi-thickness chiplets for in-substrate chiplet integration into wafer cavities of a host wafer using lateral dielectric material.

FIG. 3 is a schematic top view of a second set of multi-thickness chiplets for in-substrate chiplet integration into wafer cavities of a host wafer using lateral dielectric material.

FIG. 4 is a schematic top view of metal backfill plugs for in-substrate multi-thickness chiplet integration into wafer cavities of a host wafer using lateral dielectric material.

FIG. 5 is a schematic cross-sectional view of a device having in-substrate multi-thickness chiplet integration into wafer cavities of a host wafer using lateral dielectric material.

Throughout this description, elements appearing in figures are assigned three-digit or four-digit reference designators, where the two least significant digits are specific to the element and the one or two most significant digit may be the figure number where the element is first introduced or fabricated. An element that is not described in conjunction with a figure may be presumed to have the same characteristics and function as a previously-described or subsequently-described element having the same reference designator.

### DETAILED DESCRIPTION

### Description of Apparatus

The following describes improved wafers, die, chips and fabrication techniques thereof for electronic assemblies having in-substrate chips (e.g., chiplets) integrated into wafer cavities of a host wafer, such as using lateral bonding material. The host wafer can have pre-fabricated interconnects and integrated circuitry, such as passive components, that connect to multi-thickness chiplet level microelectronics transistor chips integrated in through-wafer cavities of the wafer. This may form an assembly for integrated circuit devices where the chips contain active circuits from at least one semiconductor technology and the wafer contains passive (or active) circuits from another semiconductor technology (often a cheaper and larger scale technology). Using a low-cost large-diameter wafer integration platform for the higher cost chips with active devices allows for much faster manufacturing of the assembled circuits, at larger scale and lower cost.

The electronic assembled circuit may integrate multi-thickness chiplets having one type of components into a carrier wafer having a different type of components. The electronic assembled circuit may integrate multi-thickness chiplets having high-performance integrated circuits, such as Gallium Nitride (GaN) radio frequency (RF) integrated circuits (ICs) into host wafers having other integrated circuits, such as silicon-based integrated circuits, in a manner that is inexpensive and has high manufacturing yields and short manufacturing cycles. The high performance multi-thickness RF ICs, chips (or chiplets) can have type III-V transistors or other types of transistors and passives, and can be integrated together with resistors, inductors, capacitors and matching networks, as well as active devices from another semiconductor technology into the host wafer. For example, the multi-thickness RF ICs can be one type of semiconductor technology that is integrated together with resistors, inductors, capacitors, matching networks, and optionally active devices from another semiconductor technology that are part of the host wafer. A multi-thickness chiplet may be a chip including the circuitry, material, and/or devices noted above in this paragraph. It may also be a chip or small chip having active microelectronic (i.e., transistor) devices, CMOS devices, microwave IC devices and/or radio frequency (RF) IC devices. It may also be a chip or small chip having a SAW, BAW or other acoustic wave device. A multi-thickness chiplet may have a footprint or top surface area that is half, a third a fifth or less than a fifth of that of a computer processor chip (e.g., 8086, P3, P4, etc.).

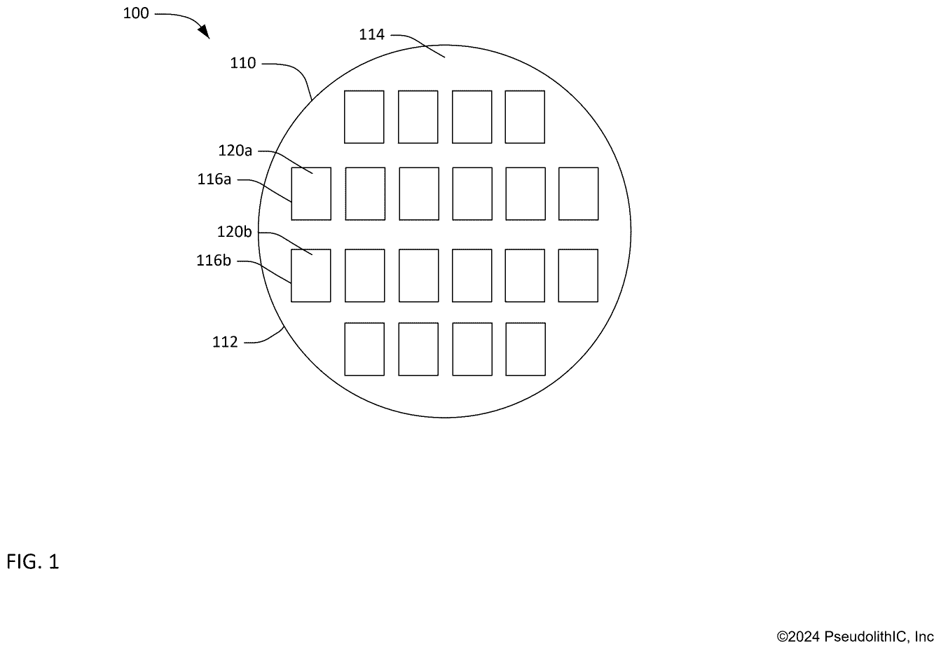

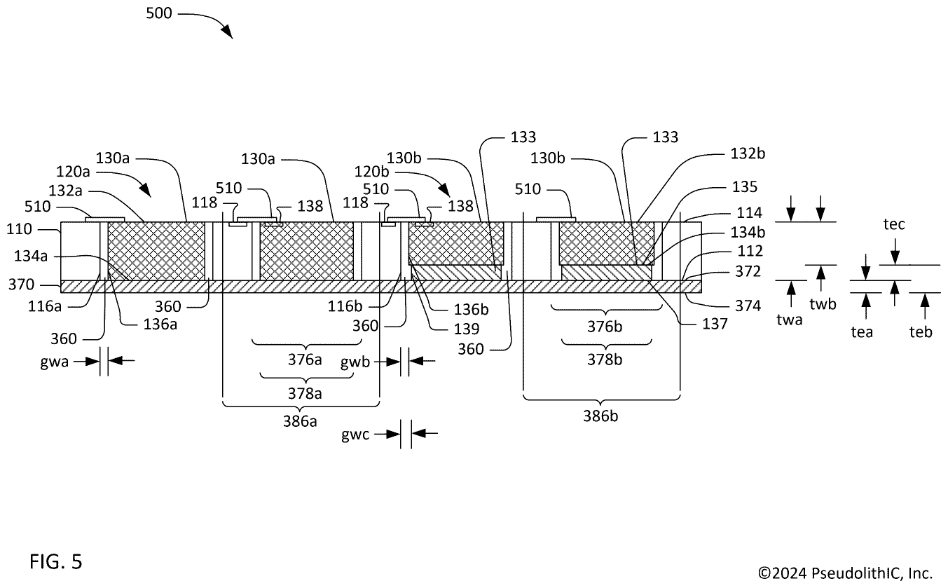

FIG. 1 is a schematic top view 100 of a host wafer 110 having cavities 120a and 120b for in-substrate multi-thickness chiplet integration into the wafer cavities 120a and 120b of a host wafer 110, such as using lateral bonding material. Host wafer 110 has back surface 112 and front surface 114 as shown in FIG. 5. Host wafer 110 and each cavity 120a and 120b has side surfaces 116a and 116b respectively. Each of side surfaces 116a and 116b may be a vertical or sidewall surface between the back surface 112 and front surface 114. There may be 3, 4 or more side surface 116a and 116b in each of the cavities. Typically, there are 4 side surfaces in each of the cavities. Each cavity 120a and 120b may have a minimum of one sides (e.g., may be a circle) and up to an infinite number of sides, but preferably has 4 sides.

Wafer 110 may be or include (e.g., as a mixture of materials or as material layers) silicon, silicon germanium, silicon on insulator, gallium arsenide, indium phosphide, aluminum nitride, diamond, silicon carbide, quartz, alumina. If the wafer only contains interconnections and passive components, it can be a dielectric such as glass, quartz, alumina, or another ceramic. The host wafer 110 may be a Si CMOS wafer. The host wafer 110 may have layers of one or more of these materials in the form of an oxide material, crystalline material and polycrystalline material and/or amorphous material. Wafer 110 may include at least one of resistors, capacitors, inductors, through substrate vias, dielectric layers, metal layers (e.g., signal traces or signal planes). Wafer 110 may include at least one layer of silicon, silicon carbide (SiC), quartz, or another semiconductor wafer material.

Wafer 110 may include areas to be diced into integrated circuits, each having passive integrated components (e.g., signal traces, interconnects and conductive vias, resistors, inductors and/or capacitors), and at least two multi-thickness chiplets that each have a single transistor and/or a plurality of transistors. Silicon is an advantageous choice for wafer 110, because it takes advantage of having a lower expense than other materials; and/or of known microelectronics fabrication processes and of scaling and manufacturing capabilities.

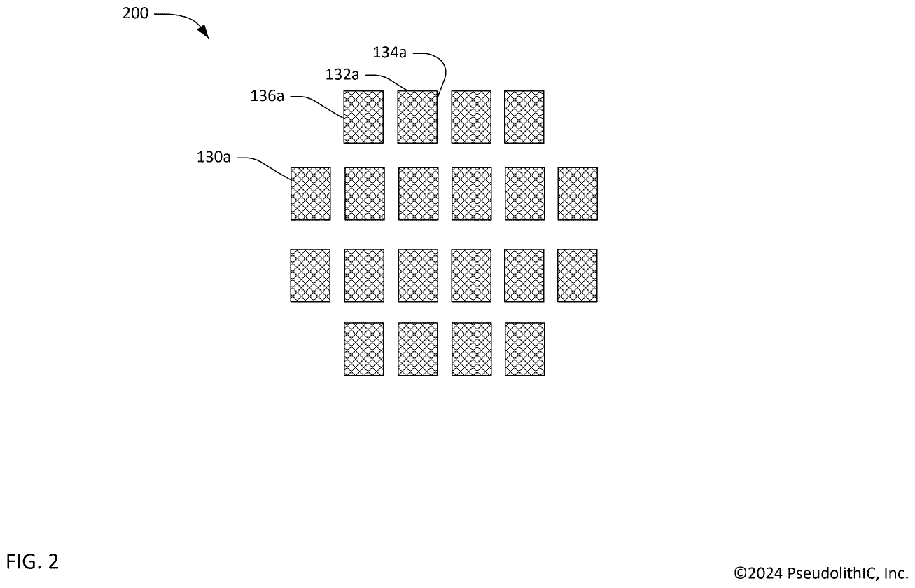

FIG. 2 is a schematic top view 200 of a first set of multi-thickness chiplets 130a for in-substrate multi-thickness chiplet integration into wafer cavities 120a of a host wafer 110, such as using lateral bonding material. Chiplets 130a have frontside 132a (e.g., a frontside surface), a backside 134a (e.g., a backside surface), and a thickness twa as shown in FIG. 5. Each chiplet 130a has side surfaces 136a, such as a vertical or sidewall surfaces between the frontside surface 132a and backside 134a. The chiplets 130a could have anywhere between 0 (e.g., have a curved perimeter, be a circle, be an oval, etc.) and an infinite number of sides 136a. There may be 3, 4 or more side surface 136a. Sometimes there are 4 side surfaces. The number of side surfaces 136a of each chiplet 130a may be the same as the number of surfaces 116a.

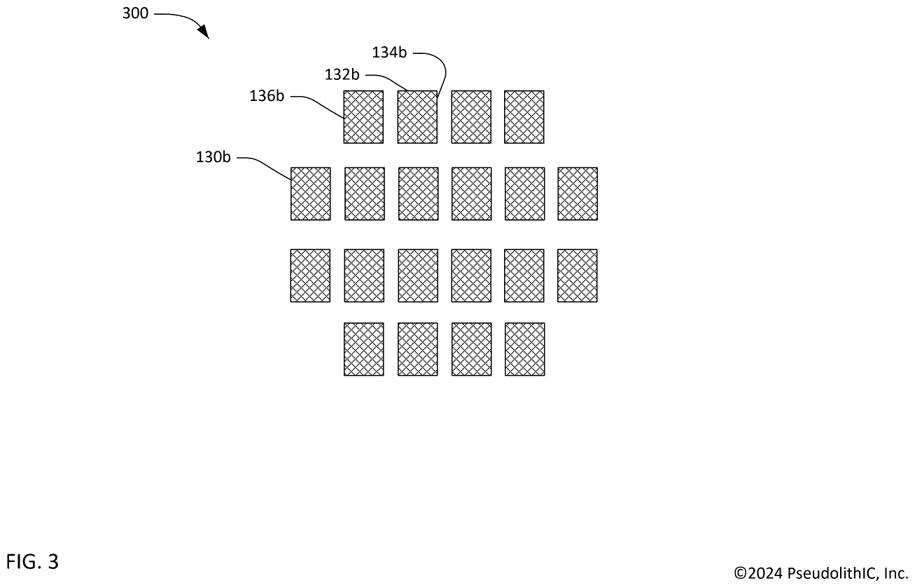

FIG. 3 is a schematic top view 300 of a second set of multi-thickness chiplets 130b for in-substrate multi-thickness chiplet integration into wafer cavities 120b of a host wafer 110, such as using lateral bonding material. Chiplets 130b have frontside 132b, a backside 134b, and a thickness twb as shown in FIG. 5. Each chiplet 130b has side surfaces 136b, such as a vertical or sidewall surfaces between the frontside surface 132b and backside 134b. The chiplets 130b could have anywhere between 0 and an infinite number of sides 136b. There may be 3, 4 or more side surface 136b. Sometimes there are 4 side surfaces. The number of side surfaces 136b of each chiplet 130b may be the same as the number of surfaces 116b.

Chiplets 130a and 130b may each be or include (e.g., as a mixture of materials or as material layers) silicon, silicon germanium, silicon-on-insulator, gallium arsenide, indium phosphide, aluminum nitride, quartz, alumina, gallium nitride, silicon carbide. The chiplets 130a and 130b may each have layers of one or more of these materials in the form of an oxide material, crystalline material and polycrystalline material and/or amorphous material. There may be different electrical component ones or types of each of chiplets 130a and 130b that are manufactured separately from each other. That is, each of chiplets 130a may be manufactured separately from each other, and each of chiplets 130b may be manufactured separately from each other. Also, chiplets 130a may be manufactured separately from chiplets 130b. Each of chiplets 130a and 130b can include a GaN, InP or GaAs or any other industry-known electrical component and can be fabricated on a substrate such as Si, SiGe, InP, GaAs, SiC, Alumina, or diamond, or any other substrate known in the industry.

Chiplets 130a and 130b or types of chiplets 130a and 130b may include RF switches, transmit and/or receive circuits; power switches, amplifiers and circuits such as using GaAs, InP, GaN; and/or transistors such as Si CMOS transistors. They may have smaller and more expensive electrical components than those of wafer 110. There may be hundreds, thousands or hundreds of thousands of chiplets 130a and 130b embedded in one wafer 110. Wafer 110 may have more passive components, lower cost components, routing (e.g., traces, conductive vias and interconnections) than those of chiplets 130a and 130b. Wafer 110 may be fabricated using different microelectronic fabrication techniques or processes than used to fabricate chiplets 130a and 130b.

Chiplets 130a and 130b can be made of different materials than wafer 110. For example, wafer 110 can be a silicon wafer while chiplets 130a and 130b can be a type III-Nitride material component chip. Chiplets 130a and 130b may each be or include an integrated circuit having passive integrated components (e.g., signal traces, interconnects and conductive vias, resistors, inductors and/or capacitors), a single transistor and/or a plurality of transistors.

The chiplets 130a and 130b, may each include at least one of transistor circuitry and interconnects to contact pads on a frontsides 132a and 132b of the chiplets 130a and 130b. The chiplets 130a and 130b may be high-end pre-fabricated active device chiplets that are integrated into wafer 110 through pick and place assembly, such as into cavities 120a and 120b, on a temporary wafer with an adhesive laminate or simply on an adhesive laminate.

The chiplets 130a and 130b, may each be compound semiconductor wafers that are used as transistor building blocks into heterogeneously-integrated silicon circuits including wafer 110. The chiplets 130a and 130b may be from wafers processed at foundries using qualified processes, and later diced into the chiplets prior to the heterogenous integration. Based on the chiplets technology (e.g., InP, GaAs, GaN, . . . ) and based on the foundry utilized, the final chiplet thicknesses may range from 10 microns to up to 150 microns (6-mil-thick). In some cases, one or more of chiplets 130b is 2× thinner than one or more of chiplets 130a.

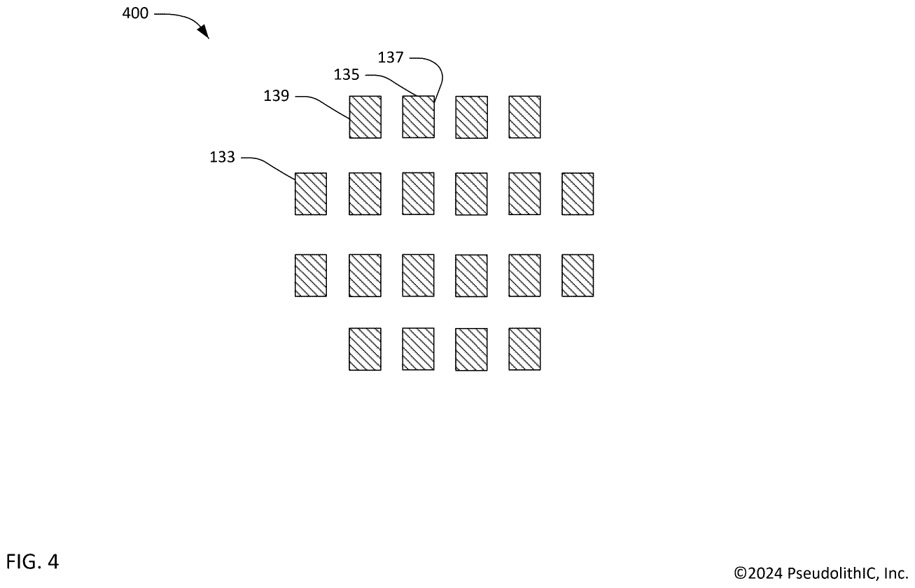

FIG. 4 is a schematic top view 400 of metal backfill plugs 133 for in-substrate multi-thickness chiplet integration into wafer cavities 120b of a host wafer 110, such as using lateral bonding material. Plugs 133 have frontside 135, a backside 137, and a thickness tec as shown in FIG. 5. Each plug 133 has side surfaces 139, such as a vertical or sidewall surfaces between the frontside surface 135 and backside 137. The plugs 133 could have anywhere between 0 and an infinite number of sides 139. There may be 3, 4 or more side surface 139. Sometimes there are 4 side surfaces. The number of side surfaces 139 of each plug 133 may be the same as the number of surfaces 116b or 136b. In some cases, plugs 133 are “backside metal fills” to thicken the chiplets 130b. This enables good thermal conductivity for all the embedded chiplets 130b, no matter their original thickness.

FIG. 5 is a schematic cross-sectional view of a device 500 having in-substrate chiplets 130a and 130b integrated into wafer cavities 120a and 120b of a host wafer 110 using lateral bonding material 360. Device 500 may include the devices of FIGS. 1-4. As shown, thickness twb chiplets 130b is less than thickness twa of chiplets 130a; and a metal backfill plug 133 is formed on backside 134b of chiplets 130b.

Device 500 may be an electronic assembly having a backside capping layer 370 having a top surface 372 and a back surface 374. Device 500 has a host wafer 110 having back surface 112 and front surface 114, with the back surface 112 of the wafer bonded to the top surface 372 of a backside capping layer 370 except for cavities 120a and 120b in the wafer 110 formed over a plurality of areas 376a and 376b of the top surface 372. The cavities may extend from back surface 112, through the wafer and to front surface 114. The cavities have side surfaces 116a and 116b. The back surface 112 of the wafer may be directly attached to and touching the top surface 372. The bond between the back surface 112 and the top surface 372 may be a covalent, chemical or atomic bond.

Chiplets 130a, such as a plurality of chips, have a backside 134a and a frontside 132a, with the backsides 134a of the chiplets 130a bonded directly to at least portion 378a of the plurality of areas 376a of the top surface 372 of the backside capping layer 370. Portion 378a may be the footprint of the chiplet 130a on top surface 372 within the cavity 120a. A gap gwa between side surfaces 116a and 136a may be the difference between area 376a and portion 378a. The backside 134a may be directly attached to and touching the top surface 372. The bond between the backside 134a and the top surface 372 may be a covalent, chemical or atomic bond. Areas 376a and portions 378a have a thickness “tea” of the backside capping layer 370.

The cavities 120a may be through-substrate holes or through substrate holes etched in the wafer at the areas 376a. The, chiplets 130a may be embedded into the wafer 110 at the substrate holes or at cavities 120a.

A lateral bonding material 360 extends between side surfaces 136a of the chiplets 130a and the side surfaces 116a of the wafer or cavities. The lateral bonding material 360 may mechano-chemically bond the side surfaces 136a of the chiplets 130a to the side surfaces 116a of the wafer. The lateral bonding material 360 may form a mechanical and/or a chemical bond to the side surfaces 136a and to the side surfaces 116a. The bonding may be a mechano-chemical bond. In some cases, the lateral bonding material 360 is a molded material that is molded between chiplets 130b and wafer 110 within cavities 120b. In some cases, the dielectric material 360 has a coefficient of thermal expansion between or equal to one of those of the wafer 110, and of the chiplets 130a and/or 360b.

Chiplets 130b, such as a plurality of chips, have a backside 134b and a frontside 132b, with the backsides 134b of the chiplets 130b bonded to at least portion 378b of the plurality of areas 376b of the top surface 372 of the backside capping layer 370.

Backsides 134b of chiplets 130b may be directly bonded to metal backfill plugs 133 which are in turn boded directly to portions 378b of the backside capping layer 370. Plugs 133, such as a plurality of metal backfill material, have a backside 137 and a frontside 135, with the frontside 135 bonded to backside 134b of chiplet 130b and the backsides 137 bonded to at least portion 378b of the backside capping layer 370. Backsides 134b may be bonded to a surface of metal backfill plugs 133 that is the same size as portions 378b. Plugs 133 may have a perimeter that is the same as that of portions 378b. Plugs 133 may have a perimeter that is less than that of chiplet 130b as shown. In other cases, the two perimeters are the same. In other case, plugs 133 may have a perimeter that is greater than that of chiplet 130b.

Portion 378a may be the footprint of the chiplet 130a or plug 133 on top surface 372 within the cavity 120b. A gap gwb is between side surfaces 116b and 136b. A gap gwc is between side surfaces 139 of plug 133 and 136b. Gap gwc may be the difference between area 376b and portion 378b. As shown, gap gwc is greater than gap gwb. In other cases, these gaps may be the same. In other case, gap gwc is less than gap gwb.

The backside 134b may be directly attached to and touching the frontside 135 and backside 137 may be directly attached to and touching the top surface 372. The bonds between the backside 134b and the frontside 135 and between backside 137 and the top surface 372 may be a covalent, chemical or atomic bond. Portions 378b have a thickness “teb” that is thickness “tea” the backside capping layer 370 plus a thickness “tec” of plug 133. It can be said that thickness “teb” is a thickness of the backside capping layer 370 due to plug 133 being a metal backfill plug. Thickness “teb” may be a thickness of the backside capping layer 370 due to plug 133 being of the same material as layer 370.

The metal backfill plug 133 may be from a copper metal deposition layer; an electroplated metal layer; and/or a sputtered metal seed layer (e.g., titanium Ti and/or copper Cu) plated with a plate metal such as copper on the formed or deposited on backsides 134b of the chiplets 130b. The seed layer may be a Ti/Cu 200/2,000 angstrom (A) wafer-level backside sputtering on the backside 134b of the chips 103b, Plugs 133 may be backside metal backfill adjusted in width, length and thickness ranging from 0.1 μm to 1,000 microns thick using an electroplating process. Plugs 133 may be between 5 and 60 microns thick, and chiplets 130b may be between being 200×200 μm thick.

In some cases, plugs 133 are formed of a metal such as copper, gold, silver, titanium, tungsten, or the like. They may be formed of molybdenum, tungsten, lithium, nickel, tantalum, steel, beryllium, or the like. They may be formed of a material that includes or is a combination of the metals above. They may be formed of an alloy or ceramic. Plugs 133 may have a footprint that is between 20 microns and 20 microns by between 5,000 microns W and 5,000 microns; or that has an area ranging from 0.04 mm² and 25 mm². Chiplets 130a and 130b may have a footprint that is between 100 microns and 100 microns by between 5,000 microns and 5,000 microns; or that has an area of 0.1 to 25 mm².

Layer 370 may be formed of a metal such as copper, gold, silver, titanium, tungsten, and the like. It may be formed of molybdenum, tungsten, lithium, nickel, tantalum, steel, beryllium, or the like. It may be formed of a material that includes or is a combination of the metals above. It may be formed of an alloy or ceramic. Layer 370 and plugs 133 may be the same material. They may be different materials.

In some cases, the backside capping layer 370 is an electroplated layer formed on the metal backfill plugs 133 and has a planarized back surface 374. The backside capping layer 370 may be an electroplated layer formed on the chiplets 130a and 130b. In some cases, the metal backfill plugs 133 are formed from an electroplated layer formed on the planarized front surface 372 backside capping layer 370.

As shown thickness twa of chiplets 130a is greater than thickness twb of chiplets 130b, and thickness “tea” of the metallization under of chiplets 130a is less than thickness “teb” of the metallization under of chiplets 130b. The thickness teb of the backside capping layer 370 or of the metallization under of chiplets 130b may be described as including metal backfill plugs 133 between the backsides 134b of the chiplets 130b and the thickness “tea” of the backside capping layer 370.

The cavities 120b may be through-substrate holes or through substrate holes etched in the wafer at the areas 376b. The, chiplets 130b may be embedded into the wafer 110 at the substrate holes or at cavities 120b.

A lateral bonding material 360 extends between side surfaces 136b of the chiplets 130b and the side surfaces 116b of the wafer or cavities. The lateral bonding material 360 may mechano-chemically bond the side surfaces 136b of the chiplets 130b to the side surfaces 116b of the wafer. The lateral bonding material 360 may form a mechanical and/or a chemical bond to the side surfaces 136b and to the side surfaces 116b. The bonding may be a mechano-chemical bond. In some cases, the lateral bonding material 360 is a molded material that is molded between chiplets 130b and wafer 110 within cavities 120b.

The lateral bonding material 360 extends between side surfaces 139 of the plugs 133 and the side surfaces 116b of the wafer or cavities. The lateral bonding material 360 may mechano-chemically bond the side surfaces 139 of the plugs 133 to the side surfaces 116b of the wafer. The lateral bonding material 360 may form a mechanical and/or a chemical bond to the side surfaces 139 and to the side surfaces 116b. The bonding may be a mechano-chemical bond. In some cases, the lateral bonding material 360 is a molded material that is molded between plugs 133 and wafer 110 within cavities 120b.

The bond between material 360, side surfaces 136a 136b or 139; and surface 116a or 116b may be an a covalent, chemical or atomic bond. It may be an adhesive bond formed by pressure forming the material 360 into gaps where the material 360 is disposed between those surfaces.

Dielectric material 360 is not a metal and is an electrical insulator. Dielectric material 360 may be or include material that is not conductive, is not a semiconductor, is a plastic, is not an alloy, is a bio-material. Material 360 may be an epoxy. It may be epoxy with a silica particles.

It may be epoxy with SiO2 particles. Material 360 may be a lateral non-electrically conductive epoxy material or a dielectric material. Material 360 may be a non-electrically conductive epoxy material, a non-electrically conductive laminate material or a dielectric material. Material 360 may mechano-chemically bond the side surfaces of the chiplets 130a and 130b to the side surfaces 116a and 116b of the wafer 110.

Material 360 may have dielectric characteristics such that when placed in an electric field, the electric charges do not flow through the material. Electric charges slightly shift from their average equilibrium positions, causing dielectric polarization that causes positive charges to flow in the direction of the field and negative charges to shift in the opposite direction of the field. This phenomenon yields an internal electric field, which in turn reduces the overall electric field within the dielectric material.

The lateral bonding material 360 is disposed in gaps gwa between the side surfaces 136a of each of the chiplets 130a and the side surfaces 116a of the corresponding wafer cavity 120a that each chiplet 130a is disposed in. The gap gwa has a width gw of between ⅕ (one fifth) and 10 times a thickness twa of the chiplets 130a.

Chiplets 130b may have widths between side surfaces 136b that are different or greater than widths 139 between side surfaces of the plugs 133. The lateral bonding material 360 is disposed in gaps gwb between the side surfaces 136b of each of the chiplets 130b and the side surfaces 116b of the corresponding wafer cavity 120b that each chiplet 130b is disposed in. The gap gwb has a width gwb of between ⅕ (one fifth) and 10 times a thickness twb of the chiplets 130b. The lateral bonding material 360 is disposed in gaps gwc between the side surfaces 139 of each of the plugs 133 and the side surfaces 116b of the corresponding wafer cavity 120b that each plug 133 is disposed in. The gap gwc has a width gwc of between ⅕ (one fifth) and 15 times a thickness twb of the chiplets 130b.

The aspect ratio, as defined by ratio of the thickness twa of the chiplets 130a (and optionally of the wafer 110) to the width gwa (e.g., the minimum distance between the vertical side of the chip 130a and the side of the cavity 116a) can be on the order of 100:1, but typically would be 10:1. In some cases, thickness twa is between 500 and 2000 μm and width gwa is between 5 and 20 μm. There may be a similar aspect ratio between thickness twb and width gwb. In some cases, thickness twb is between 500 and 2000 μm and width gwb is between 5 and 20 μm. In some cases, thickness twc is between 500 and 2000 μm and width gwc is between 2 and 15 μm.

Material 360 may be formed using a printing process to print a bump of the lateral bonding material 360 into gaps gwa, gwb and gwc between the side surfaces of the chiplets and plug and the side surfaces of the wafer 110 using a permanent screen, such as using the wafer with cavity as a screen to be printed on by the printer. The printing process may include a screen-printing process, where the lateral bonding material 360 is pressed by a squeegee that spreads a ball of that bonding material over the surfaces 134a, 134b and 112, and into the gaps gwa, gwc and gwb.

The wafer 110 thickness may be from 10 to 2,000 microns. It may be between 50 and 100 μm. The thickness twa (which may also be a thickness of the wafer 110) may be between 20 and 200 microns. It may be between 50 and 125 μm. It may be 75 μm. The thickness twa of one, many or all of the chiplets 130a may be that same as that of the wafer. The thickness twb of one, many or all of the chiplets 130b may be between 5 and 95 percent of the thickness of the wafer. It may be between may be between 20 and 50 percent of the thickness of the wafer. A thickness twc of plug 133 may be in a range between 5 and 60 microns, and/or the chiplets 130b may have a width in a range between 200×20 μm.

A thickness “tea” of the backside capping layer may be between 3 and 300 microns. It may be between 5 and 100 microns. It may be between 10 and 50 microns. It may be 10-20 microns thick.

Each of the chiplets 130a and 130b may have between 3 and 6 sides. They may have 4 sides. The sides may be straight, curved or wavy in profile as viewed from a top perspective. The cavities 120a and 120b may have the same number of and sides corresponding to the shapes of the sides of the chiplets 130a and 130b, respectively. In some cases, chiplets 130a are formed by a different foundry process than the chiplet 130b.

The backside capping layer 370 may be a high-thermal-conductivity backside metallization layer that improves heat transfer from the chiplets 130a, plug 133 and chiplet 130b to the wafer 110. Layer 370 may be a thermal plane that improves heat conduction away from the chiplets by increasing thermal conduction from the chiplets 130a, plug 133 and chiplet 130b and to layer 370 and/or wafer 110. The backside capping layer 370 may have a coefficient of thermal conductivity greater than those of the wafer 110 and of the chiplets 130a and 130b. Layer 370 may be a material in direct contact with the chiplets 130a and plug 133 to increase thermal conduction between the materials of the chiplets 130a, plug 133 and chiplet 130b, and the material of layer 370. In some cases, the backside capping layer 370 has a coefficient of thermal expansion between any two of or equal to one of the wafer 110, plug 133 or chiplets 130a.

The plug 133 may be a high-thermal-conductivity metal backfill plug that improves heat transfer from the chiplets 130b to the wafer 110. Plug 133 may be a thermal plane that improves heat conduction away from the chiplets by increasing thermal conduction from the chiplet 130b and to layer 370 and/or wafer 110. Plug 133 may be a material in direct contact with the chiplets 130b to increase thermal conduction between the materials of the chiplets 130b and the material of layer 370. In some cases, the plug 133 has a coefficient of thermal expansion between any of or equal to one of the wafer 110, chiplets 130b or layer 370.

Interconnects 510 may be formed directly on the lateral bonding material 360 and connect electrical (e.g., power, ground and/or signal) contacts 138 of the chiplets 130a and 130b to contacts 118 of the wafer 110. Interconnects 510 may include direct interconnect routing or traces that is formed directly on the lateral bonding material (e.g., without any dielectric/air gap), and that extends from the chiplets to wafer electrical routing. Interconnects 510 may be bonded to material 360, directly attached to material 360, touching material 360 and/or have no air gap between the interconnect and the material 360. The interconnect routing may include low loss high-performance DC, RF, and mm-wave routing from the chiplets 130a and 130b, directly on the lateral bonding material, and to wafer electrical routing. Interconnects 510 may be directly on material 360 by being bonded to and/or directly attached to (e.g., touching) the top surface of the lateral bonding material 360.

Interconnects 510 may be formed by electroplating a pattern of interconnects 510 through a photoresist and then dissolving the photoresist. Interconnects 510 may be formed by deposition of, masking over the pattern of interconnects 510 and etching away non-patterned parts of a conductive material such as a metal. Beneficially, interconnects 510 can be formed without the cost, processing or material height of using solder or contact bumps on contacts of either the chiplets 130a, chiplets 130b or the wafer 110.

Each chiplet 130a and 130b may include at least one of active device circuitry and interconnects 510 to contact pads 138 on a front surface of the chiplet 130a and 130b. Each chiplet 130a and 130b may be a pre-fabricated transistor chiplet. FIG. 5 may show how the interconnect structure 510 directly sits on top of the dielectric bonding material 360 between the chiplets 130a or 130b, and wafer 110.

In some cases, wafer 110 includes an electronic integrated circuit (not shown), at least one integrated circuit contact 118 (e.g., contact pad) formed on the front wafer surface 114, and at least one through-wafer cavity 120a and/or 120b having side surface 116 that join back surface 112 to front surface 114. In some cases, a chiplet 130a is held in the through-wafer cavity 120a by a lateral bonding material 360 that attaches at least one side surface 116a of the through-wafer cavity 120a to at least one side surface 136a of the chiplet 130a. In some cases, lateral bonding material 360 fills gap gwa of the cavity, thus attaching most of the side surfaces 136a of chiplet 130a to the side surfaces 116a of through-wafer cavity 120a; however material 360 does not attach the backside 134a of chiplet 130a to top surface 372 of layer 370. In some cases, lateral bonding material 360 completely fills gap gwa of the cavity, thus attaching all of the side surfaces 136a of chiplet 130a to all of the side surfaces 116a.

In some cases, a chiplet 130b is held in the through-wafer cavity 120b by a lateral bonding material 360 that attaches at least one side surface 116b of the through-wafer cavity 120b to at least one side surface 136b of the chiplet 130b. In some cases, lateral bonding material 360 fills gap gwb of the cavity, thus attaching most of the side surfaces 136b of chiplet 130b to the side surfaces 116b of through-wafer cavity 120b; and material 360 attaches the backside 134b of chiplet 130b between portion 378b and area 376b to top surface 372 of layer 370. In some cases, lateral bonding material 360 completely fills gap gwb of the cavity, thus attaching all of the side surfaces 136b of chiplet 130b to all of the side surfaces 116b.

In some cases, a plug 133 is held in the through-wafer cavity 120b by a lateral bonding material 360 that attaches at least one side surface 116b of the through-wafer cavity 120b to at least one side surface 139 of the plug 133. In some cases, lateral bonding material 360 fills gap gwc of the cavity, thus attaching most of the side surfaces 139 of plug 133 to the side surfaces 116b of through-wafer cavity 120b; however material 360 does not attach the backside 137 of plug 133 to top surface 372 of layer 370. In some cases, lateral bonding material 360 completely fills gap gwc of the cavity, thus attaching all of the side surfaces 139 of plug 133 to all of the side surfaces 116b.

A passivation layer (not shown) can be arranged on most of the front surface 114 of wafer 110. Conducting vias (e.g., TWVs) arranged through the passivation layer can connect the active and/or passive circuitry of wafer 110 to contacts 118 (e.g., contact pads) on front surface 114. Wafer 110 can be a silicon wafer or substrate, which allows taking advantage of known fabrication processes and manufacturability on large wafer diameters.

It is noted that wafer 110 can include any integrated circuit, active or passive, made possible by a chosen manufacturing process; for example, a CMOS manufacturing process. In some cases, the thickness of the one or more integrated circuit layers can for example be only a fraction of the thickness twa of chiplet 130a or wafer 110 (for example between 1/10 and 1/1000 of the thickness of wafer 110; for example 50 nm thick with a wafer 50 μm thick). In some cases, the thickness of wafer 110 can be reduced after fabrication of integrated circuits of the wafer and for example before etching the through-wafer cavities 120a and 120b or after filling gaps gwa, gwb and gwc with lateral bonding material 360.

Each of chiplets 130a and 130b may include one or more transistors (not shown) having its terminals connected to at least one integrated circuit contact 138 (e.g., contact pad), such as by a conductive via (not shown). Each of chiplets 130a and 130b can comprise a substrate and integrated circuit layers formed on top of its substrate, the thickness of the integrated circuit layers being for example only a fraction of the thickness of the substrate (for example between 1/10 and 1/1000 of the thickness of the substrate). In some cases, the total thickness of each of chiplets 130a and 130b is smaller than the total thickness of host wafer 110. In some cases, lateral bonding material 360 contacts the side surfaces 136a of chiplet 130a along most of their height (at least 50% of the height, starting from close to the top surface of chiplet 130a). Preferably, lateral bonding material 360 contacts essentially all of the side surfaces 136a, 136b and 139. Preferably, lateral bonding material 360 fills gaps gwa, gwb and gwc, completely up to a level essentially flush with the front surface 114 of host wafer 110.

In some cases, lateral bonding material 360 holds the chiplets 130a and 130b such that the chiplets frontsides 132a and 132b are flush with the front surface 114. Being “flush” may be understood as meaning that the two surfaces are in a same plane, or have, with respect to each other, a small or negligible height difference. The two surfaces may be flush, such as resulting from the process of material 360 permanently attaching chiplets 130a and 130b to the side surfaces 116a and 116b of through wafer cavities 120a and 120b while both the chiplet frontsides 132a and 132b and the front surface 114 are flush or planar such as when attached temporarily to a planar layer or material. The frontsides 132a and 132b and the front surface 114 may be flush, such as resulting from polishing or CMP of those surfaces.

In some cases, layer 370 without plug 133 has flat planar, continuous surface and a constant thickness tea, such as where the back surfaces 134a, 137 and backside surface 112 of the wafer are all at the same vertical, planar level. In some cases, layer 370 with plug 133 has a non-flat surface and a non-constant thickness, such as where the back surfaces 134b of the chiplets 130b and backside surface 112 of the wafer vary in height and are not planar. In one case, the thickness of layer 370 varies between the chiplets and wafer by being a certain thickness tea for the wafer 110 and chiplets 130a, but having another thickness teb that includes the thickness tec of the plug 133 for chiplets 130b.

The chiplets 130a and 130b and wafer exposed bottom surfaces 112 may be simultaneously polished such as by chemical mechanical polishing (CMP) such as before layer 370 is bonded. In other cases, they are not polished. The exposed surfaces 132a, 132b and 112 may be surfaces with the electrical components that are then interconnected with the conductors 510. In some cases, chiplets 130a and 130b can be arranged such that a surface front surface is arranged and maintained parallel to the front surface 114 of wafer 110. This capability can be used to increase the number of component chiplets 130a and 130b embedded in wafer 110, and/or when the side surface of chiplets 130a and 130b maintained parallel to the front surface of wafer 110 has a specific function. This might be the case, for example, when chiplet 130a and/or 130b is a semiconductor laser chip and its side surface is a laser emitting side.

It is considered that the host wafer 110 can be vertically diced at dicing lines (shown by the vertical bars in FIG. 5) along a perimeters 386a and/or 386b of the wafer around at least one chiplet to form a chip having the at least one chiplet and an area of the wafer surrounding the at least one chiplet. In some cases, wafer 110 is vertically diced at dicing lines along perimeters 386a and 386b around at least one of each of chiplets 130a and 130b to form at least two chips each having the at least one chiplets 130a or 130b and an area of the wafer surrounding the at least two chiplets. Wafer 110 may be vertically diced along perimeters 386a and 386b around numerous or all of chiplets 130a and 130b to form chips each having the at least one of chiplets 130a or 130b and an area of the wafer surrounding the chiplets. Wafer 110 may be vertically diced along perimeters around two or more of chiplets 130a or 130b to form chips and an area of the wafer surrounding the chiplets. Wafer 110 may be vertically diced along perimeters around two or more of chiplets 130a and 130b to form chips and an area of the wafer surrounding the chiplets.

The diced chips having the chiplet(s) may each be a structure where the chiplets are embedded within the volume of a silicon/CMOS wafer 110 using a dielectric sidewall bonding technique to form material 360. The diced chips may be structures where chiplets of different thicknesses can be co-integrated into the same silicon wafer 110 using the same dielectric sidewall bonding technique of material 360, while maintaining high-thermal-conductivity on the backside of all the chiplets.

Beneficially, the use of a host wafer having circuitry and multi-thickness chiplets within and laterally bonded to the sidewalls of cavities of the wafer include creating electronic assemblies or chips that are low cost and volume-scalable and mitigating coefficients of thermal expansion mismatch between the silicon wafer frame 110 and the chiplets. This use also allows for use of lateral bonding material 360 such as a dielectric which allows for direct interconnect routing 510 from the chiplets to the wafer 110 electrical routing (e.g., without a dielectric/air gap); low loss high-performance direct current (DC), radio frequency (RF), and mm-wave signals between the chiplets and the wafer 110 electrical routing. This use also adds a new “degree of freedom” when the chiplets to be integrated into the wafer 110 are of different thicknesses (or thinner than an interposer used for chiplet integration), without degrading the performance of the chiplets (the chiplet performance can even be improved due to the thicker thermal heat spreader of layer 370 and plug 133 on the back of the chiplets 130b).

Beneficially, the lateral mechano-chemical chiplet bonding and/or use of the material 360: (1) is low cost such as by using low cost processes and materials for material 360; and (2) is volume-scalable such as by allowing the size and number of chiplets 130a and 130b to be easily changed. Beneficially, in that the lateral mechano-chemical chiplet bonding and/or use of the material 360 mitigates coefficient of thermal expansion mismatch between the silicon wafer frame 110 and the chiplets 130a and 130b, such as by the material 360 having a coefficient of thermal expansion close to one of, or between that of, wafer 110 and the chiplets 130a and 130b. Beneficially, the lateral mechano-chemical chiplet bonding and/or use of the material 360 allows: (1) direct interconnect routing from the chiplets 130a and 130b to the wafer 110 electrical routing (e.g., with no dielectric/air gap); and (2) low loss high-performance DC, RF, and mm-wave signal transfer between the chiplets 130a and 130b and the wafer 110 electrical routing, where (1) and (2) can use interconnects 510 between contacts of the chiplets 130a and 130b and wafer 110 that can be formed on the surface of material 360.

Beneficially, the lateral mechano-chemical chiplet bonding and/or use of the material 360, as compared to using a semiconductor or conductor material in place of material 360, reduces noise and changes in frequency in interconnect routing from the chiplets 130a and 130b to the wafer 110 electrical routing. Beneficially, the lateral mechano-chemical chiplet bonding and/or use of the material 360, as compared to using a semiconductor or conductor material in place of material 360, reduces capacitance in high frequency signals and has lower signal loss in interconnect routing from the chiplets 130a and 130b to the wafer 110 electrical routing. Beneficially, the lateral mechano-chemical chiplet bonding and/or use of the material 360, as compared to using a semiconductor or conductor material in place of material 360, reduces the cost of the material of and processing for forming the lateral bonding material between the chiplets 130a and 130b and the wafer 110.

In addition to those benefits, that lateral mechano-chemical bonding of material 360 and/or use of backside capping layer 370 provide: a high-thermal-conductivity backside metallization 370 of the restructured wafer 500 to improve heat transfer from the chiplets 130a and 130b to the plug 133, wafer 110 and layer 370 which may be a “thermal plane” for the device 500.

Chiplets 130a and 130b are preferably pre-tested prior to bonding to material 360 and/or layer 370 to verify their functionality. As a result, the yield of the final device 500 or diced devices having chiplets 360 a and 130b is much improved over integration of component chips, in which the functionality of the component chips is not verified until after integration.

Embedding of a chiplet 130a and 130b (comprising a single chip or a plurality of component chips, etc.) in a material 360 filled cavity 120a and 120b allows a desirable increase in the increased drain of any chip-produced heat to the wafer 110 during use of the chiplet. The increased heat drain significantly beneficially limits any change in size of the chiplet due to a temperature change and allows any mechanical strain due to such size change to beneficially remain moderate. Another advantage is that the material 360 may be resilient and pliable to better absorb the size change. This heat drain is improved by connecting the bottom of the chiplet 130a and/or 130b to a metal backside capping layer 370, such as a metal plate, formed on a portion or all of the bottom surface of wafer 110. Backside capping layer 370 can be formed of metal (for example, gold) can be formed on the bottom of chiplet 130a and 130b and wafer 110. Doing so improves the thermal conductivity and interface between chiplet 130a and 130b, material 360 and wafer 110, thus further increasing the desirable drain of any chip-produced heat from the chiplet and to the layer 370 during use of the chiplet.

Advantageously, by allowing different electrical component ones of chiplets 130a and 130b to be manufactured separately from each other and from wafer 110, electronic components of those all chiplets 130a, chiplets 130b and wafer 110 can be tested separately before assembling them. In the case when one of the components of a certain electrical component chiplet 130a, chiplet 130b or of wafer 110 has poor fabrication yields, it is possible to separately spend time and money to improve the fabrication yield of that electrical component separately to produce a completed product device 500 or die thereof, having the chiplets 130a and 130b together in the cavities of the wafer 110. For example, If an electrical component of a certain chiplet type of the chiplets 130a or 130b has poor fabrication yield, it is possible to separately spend time and money to improve the fabrication yield of that electrical component chiplet type without spending time and money to improve the components of the other types of chiplets 130a, 130b or of wafer 110, to produce a completed product device 500 or die thereof, having the chiplets 130a, chiplets 130b and wafer 110.

Further, because embodiments allow fabricating different electrical component ones of chiplets 130a and 130b separately from each other and from wafer 110, all of the component types of chiplets 130a and 130b and wafer 110 do not need to be exposed to steps in the fabrication of all the different electrical component ones of chiplets 130a or 130b that could potentially damage other ones of chiplets 130a or 130b or damage wafer 110.

Thus, embodiments can reduce manufacturing costs by using small component chips in chiplets 130a and 130b having specific features and made of exotic expensive materials, in combination with integrated circuits of other chiplets 130a and/or 130b and/or wafer 110 having more common features and made of cheaper common materials.

According to embodiments, any of chiplets 130a and 130b can include a GaN, InP or GaAs electrical component and can be fabricated on a substrate such as Si, SiGe, InP, GaAs, Alumina, or diamond. In some cases, electrical components or integrated circuits of host wafer 110 can comprise metal routing and passive components fabricated at the wafer scale. In some cases, interconnection 510 can be made using conductors made out of thin films, thick, plated interconnects, multi-layers, etc. The interconnections can for example be made using the back-end steps of a manufacturing process.

### CLOSING COMMENTS

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An electronic assembly comprising:
a backside capping layer having a top surface and a back surface;
a host wafer having front and back surfaces, the back surface of the wafer bonded to the top surface of the backside capping layer except for first and a second cavities in the wafer formed over a first and a second plurality of areas of the top surface of the backside capping layer, the first and a second cavities having first and a second side surfaces;
a first plurality of chiplets having a first chiplet thickness, a first backside and a first frontside, the first backsides of the first plurality of chiplets bonded directly to at least first portions of the first plurality of areas of the top surface of the backside capping layer, wherein the first portions have a first thickness of the backside capping layer;
a second plurality of chiplets having a second chiplet thickness, a second backside and a second frontside, the second backsides of the second plurality of chiplets bonded to at least second portions of the second plurality of areas of the top surface of the backside capping layer, wherein the second portions have a second thickness of the backside capping layer; and
a lateral bonding material between side surfaces of the first and second plurality of chiplets and the first and a second side surfaces of the first and second cavities;
wherein the first chiplet thickness is greater than the second chiplet thickness;
wherein first thickness of the backside capping layer is less than the second thickness of the backside capping layer; and
wherein the lateral bonding material bonds the side surfaces of the first and second plurality of chiplets to the first and a second side surfaces of the wafer.

2. The electronic assembly of claim 1, wherein:
the second thickness of the backside capping layer includes metal backfill plugs between the second backsides of the second plurality of chiplets and the first thickness of the backside capping layer.

3. The electronic assembly of claim 2, wherein the second chiplets have widths between side surfaces of the second chiplets that are greater than widths between side surfaces of the plugs.

4. The electronic assembly of claim 3, wherein the lateral bonding material:
is also between side surfaces of the plugs and the second side surfaces of the second cavities, and
bonds the second side surfaces of the plugs to the side surfaces of the wafer.

5. The electronic assembly of claim 2, wherein:
the metal backfill plugs are a copper metal deposition layer on the second backsides of the second plurality of chiplets; and
the backside capping layer is an electroplated layer on the metal backfill plugs and has a planarized back surface.

6. The electronic assembly of claim 2, wherein the metal backfill plug, at least one of:
is a high-thermal-conductivity backside metallization layer that improves heat transfer from the second chiplets to the wafer;
improves heat conduction away from the chiplets by increasing thermal conduction from the chiplets to the backside capping layer;
is a material in direct contact with the plugs to increase thermal conduction between the materials of the chiplets 130 and that of backside capping layer; or
has a coefficient of thermal expansion between any two of those of or equal to one of those of the first chiplet, the second chiplet, the backside capping layer or the wafer.

7. The electronic assembly of claim 1, wherein the lateral bonding material is one of a non-electrically conductive lateral epoxy material or a lateral dielectric material.

8. The electronic assembly of claim 7, further comprising:
direct interconnects of conductive material from the first and second plurality of chiplets, directly on the one of the non-electrically conductive lateral epoxy material or lateral dielectric material, and to wafer electrical routing of the wafer.

9. The electronic assembly of claim 1, wherein the lateral bonding material:
includes one of a non-electrically conductive epoxy material, a non-electrically conductive laminate material or a dielectric material; and
mechano-chemically bonds the side surfaces of the first and second plurality of chiplets to the first and a second side surfaces of the wafer.

10. The electronic assembly of claim 2, wherein:
the metal backfill plugs have a thickness in a range between 5 and 60 microns, and
the second chiplets have a width in a range between 200×20 μm.

11. An electronic assembly comprising:
a host wafer having front and back surfaces, and first and a second cavities in the wafer formed over a first and a second plurality of areas of the top surface of a backside capping layer, the first and a second cavities having first and a second side surfaces;
a first plurality of chiplets having a first chiplet thickness, a first backside and a first frontside, the first backsides of the first plurality of chiplets bonded directly to at least first portions of the first plurality of areas of the top surface of the backside capping layer, wherein the first portions have a first thickness of the backside capping layer;
a second plurality of chiplets having a second chiplet thickness, a second backside and a second frontside, the second backsides of the second plurality of chiplets bonded to metal backfill plugs between the second backsides and the first thickness of the backside capping layer, wherein the second plurality of chiplets added to the metal backfill plugs have a second thickness; and
a lateral bonding material between side surfaces of the first, side surfaces of the second plurality of chiplets, side surfaces of the plugs, and the first and a second side surfaces of the first and second cavities;
wherein the first thickness is equal to the second thickness, and wherein a thickness of the first chiplets is less than a thickness of the second chiplets; and
wherein the lateral bonding material bonds the side surfaces of the first plurality of chiplets, the second plurality of chiplets and the plugs to the first and a second side surfaces of the wafer.

12. The electronic assembly of claim 11, wherein the second chiplets have widths between side surfaces of the second chiplets that are greater than widths between side surfaces of the plugs.

13. The electronic assembly of claim 11, wherein the lateral bonding material:
is also between side surfaces of the plugs and the second side surfaces of the second cavities, and
bonds the second side surfaces of the plugs to the side surfaces of the wafer.

14. The electronic assembly of claim 11, wherein:
the metal backfill plugs are a copper metal deposition layer on the second backsides of the second plurality of chiplets; and
the backside capping layer is an electroplated layer on the metal backfill plugs and has a planarized back surface.

15. The electronic assembly of claim 11, wherein the metal backfill plug, at least one of:
is a high-thermal-conductivity backside metallization layer that improves heat transfer from the second chiplets to the wafer;
improves heat conduction away from the chiplets by increasing thermal conduction from the chiplets to the backside capping layer;
is a material in direct contact with the plugs to increase thermal conduction between the materials of the chiplets 130 and that of backside capping layer; or
has a coefficient of thermal expansion between any two of those of or equal to one of those of the first chiplet, the second chiplet, the backside capping layer or the wafer.

16. The electronic assembly of claim 11, wherein the lateral bonding material is one of a non-electrically conductive lateral epoxy material or a lateral dielectric material.

17. The electronic assembly of claim 16, further comprising:
direct interconnects of conductive material from the first and second plurality of chiplets, directly on the one of the non-electrically conductive lateral epoxy material or lateral dielectric material, and to wafer electrical routing of the wafer.

18. An electronic assembly comprising:
a host wafer having front and back surfaces, and first and a second cavities in the wafer formed over a first and a second plurality of areas of the top surface of a backside capping layer, the first and a second cavities having first and a second side surfaces;
a first plurality of chiplets having a first chiplet thickness, a first backside and a first frontside, the first backsides of the first plurality of chiplets bonded directly to at least first portions of the first plurality of areas of the top surface of the backside capping layer, wherein the first portions have a first thickness of the backside capping layer;
a second plurality of chiplets having a second chiplet thickness, a second backside and a second frontside, the second backsides of the second plurality of chiplets bonded to metal backfill plugs between the second backsides and the first thickness of the backside capping layer, wherein the second plurality of chiplets added to the metal backfill plugs have a second thickness; and
a lateral bonding material between side surfaces of the first, side surfaces of the second plurality of chiplets, side surfaces of the plugs, and the first and a second side surfaces of the first and second cavities;
wherein the first thickness is equal to the second thickness, and wherein a thickness of the first chiplets is less than a thickness of the second chiplets.

19. The electronic assembly of claim 18, wherein the second chiplets have widths between side surfaces of the second chiplets that are greater than widths between side surfaces of the plugs.

20. The electronic assembly of claim 18, wherein the lateral bonding material:
is between side surfaces of the plugs and the second side surfaces of the second cavities, and
bonds the second side surfaces of the plugs to the side surfaces of the wafer.

21. The electronic assembly of claim 18, further comprising:
direct interconnects of conductive material from the first and second plurality of chiplets, directly on the one of a a non-electrically conductive lateral epoxy material or lateral dielectric material, and to wafer electrical routing of the wafer.
